(19) United States
(12) Patent Application Publication
(10) Pub. No.: US 2023/0094500 A1
(43) Pub. Date: Mar. 30, 2023

(54) GAS SUPPLY SYSTEM, SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: Kokusai Electric Corporation, Tokyo (JP)

(72) Inventors: Kentaro GOSHIMA, Toyama-shi (JP); Kaoru YAMAMOTO, Toyama-shi (JP)

(73) Assignee: Kokusai Electric Corporation, Tokyo (JP)

(21) Appl. No.: 17/950,442

(22) Filed: Sep. 22, 2022

(30) Foreign Application Priority Data
Sep. 24, 2021 (JP) 2021-156017

(51) Int. Cl. H01L 21/67

(52) U.S. Cl. CPC H01L 21/67253; H01L 21/67017

(57) ABSTRACT

There is provided a technique that includes a container in which a gas is generated; a first pipe connected between the container and a reaction chamber and including a straight pipe portion; a first pressure measurer installed at a first position of the straight pipe portion, and configured to measure a pressure of the gas; a second pressure measurer installed at a second position on a further downstream side of a flow of the gas than the first position, and configured to measure a pressure of the gas; and a controller configured to be capable of calculating a flow rate of the gas flowing through the straight pipe portion based on a pressure loss of the straight pipe portion, which is calculated from a measurement signal from the first pressure measuring part and a measurement signal from the second pressure measuring part, and controlling the flow rate of the gas.

### CROSS-REFERENCE TO RELATED APPLICATION

This application is based upon and claims the benefit of priority from Japanese Patent Application No. 2021-156017, filed on Sep. 24, 2021, the entire contents of which are incorporated herein by reference.

### TECHNICAL FIELD

The present disclosure relates to a gas supply system, a substrate processing apparatus, a method of processing a substrate, a method of manufacturing a semiconductor device, and a recording medium.

### BACKGROUND

It is conventionally known that in the manufacture of a semiconductor device, substrate processing such as a film-forming process of forming a desired oxide film on the surface of a substrate is performed. There is a substrate processing apparatus that includes a gas supply system for supplying a gas for film formation to a reaction chamber (process chamber) in which a substrate is accommodated, and processes the substrate by using the supplied gas.

Generally, a mass flow controller (MFC) is often used to control the flow rate of a gas to be supplied to a reaction chamber. In this case, the MFC for controlling the flow rate is installed in a gas supply pipe connected between a container in which a precursor is stored and the reaction chamber. However, in the manufacture of the semiconductor device, there is a demand for new techniques capable of allowing a gas of a large flow rate to stably flow regardless of the presence or absence of the MFC.

### SUMMARY

Some embodiments of the present disclosure provide a technique capable of allowing a gas of a large flow rate to stably flow.

According to embodiments of the present disclosure, there is provided a technique that includes a container in which a gas is generated; a first pipe connected between the container and a reaction chamber, and including a straight pipe portion; a first pressure measurer installed at a first position of the straight pipe portion, and configured to measure a pressure of the gas; a second pressure measurer installed at a second position on a further downstream side of a flow of the gas than the first position of the straight pipe portion, and configured to measure a pressure of the gas; and a controller configured to be capable of calculating a flow rate of the gas flowing through the straight pipe portion based on a pressure loss of the straight pipe portion, which is calculated from a measurement signal from the first pressure measuring part and a measurement signal from the second pressure measuring part, and controlling the flow rate of the gas based on a calculation result.

### BRIEF DESCRIPTION OF DRAWINGS

The accompanying drawings, which are incorporated in and constitute a part of the specification, illustrate embodiments of the present disclosure.

FIG. 1 is a longitudinal sectional view showing an outline of a vertical process furnace of a substrate processing apparatus according to embodiments of the present disclosure.

FIG. 2 is a schematic cross-sectional view taken along a line A-A in FIG. 1.

FIG. 3 is a schematic configuration diagram of a controller of the substrate processing apparatus according to embodiments of the present disclosure, in which a control system of the controller is shown in a block diagram.

FIG. 4 is a flowchart showing a substrate processing process according to embodiments of the present disclosure.

FIG. 5A is a view showing a cross section of a substrate before forming a Mo-containing film on the substrate.

FIG. 5B is a view showing a cross section of the substrate after forming the Mo-containing film on the substrate.

FIG. 6 is a flowchart showing a gas flow rate calculation process according to embodiments of the present disclosure.

FIG. 7 is a cross-sectional view for explaining a straight pipe portion through which a gas flows.

FIG. 8A is a graph for explaining a change of a flow rate of each of a first precursor gas, a first inert gas, and a second inert gas, which is set as an example in substrate processing, overt time.

FIG. 8B is a graph for explaining a change of a flow rate of each of the first precursor gas, the first inert gas, and the second inert gas, which is controlled based on a calculated flow rate of the first precursor gas, over time.

FIG. 9A is a view for explaining a method of calculating a pressure loss according to the present embodiments in which a pressure is measured at two points in a straight pipe portion.

FIG. 9B is a view for explaining a method of calculating a pressure loss according to a first modification in which a pressure is measured at five points in the straight pipe portion.

FIG. 10A is a view for explaining a case where a pressure loss is calculated by using a first pressure measuring part and a differential pressure gauge in a gas supply system according to a second modification.

FIG. 10B is a view for explaining a case where a pressure loss is calculated by using a second pressure measuring part and a differential pressure gauge.

FIG. 11 is a view for explaining the configuration of a gas supply system according to a third modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

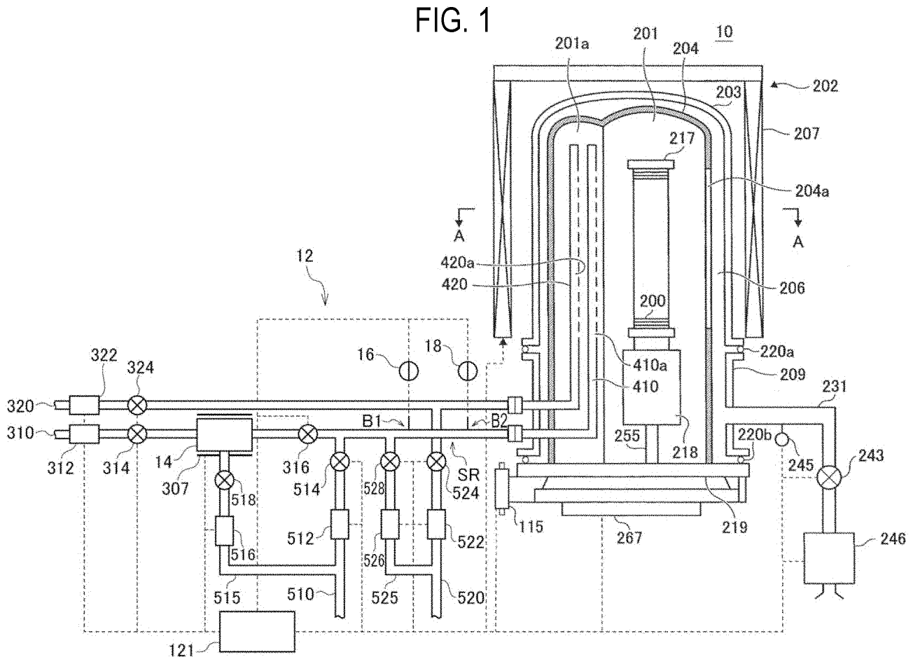

Some embodiments of the present disclosure will now be described with reference to FIGS. 1 to 11. The drawings used in the following description are all schematic, and the dimensional relationship, ratios, and the like of various elements shown in figures do not always match the actual ones. Further, the dimensional relationship, ratios, and the like of various elements between plural figures do not always match each other.

### (1) Configuration of Substrate Processing Apparatus

First, the configuration of a substrate processing apparatus 10 in which a gas supply system 12 (also referred to as a precursor gas supply system 12) according to the present embodiments will be described. In the following, the outline of the configuration of the substrate processing apparatus 10 will be first described, and the configuration related to the precursor gas supply system 12 in the configuration of the substrate processing apparatus 10 will be separately described in “(2) Configuration of Gas Supply System” later.

The substrate processing apparatus 10 includes a process furnace 202 in which a heater 207 as a heating means (a heating mechanism or a heating system) is provided. The heater 207 has a cylindrical shape and is supported by a heat base (not shown) as a support plate so as to be vertically installed.

An outer tube 203 forming a reaction container (a process container) is disposed inside the heater 207 to be concentric with the heater 207. The outer tube 203 is made of, for example, a heat resistant material such as quartz (SiO₂) or silicon carbide (SiC), and has a cylindrical shape with its upper end closed and its lower end opened. A manifold (inlet flange) 209 is disposed below the outer tube 203 to be concentric with the outer tube 203. The manifold 209 is made of, for example, a metal material such as stainless steel (SUS), and is formed in a cylindrical shape with its upper and lower ends opened. An O-ring 220a serving as a seal member is installed between the upper end portion of the manifold 209 and the outer tube 203. By supporting the manifold 209 by the heater base, the outer tube 203 becomes in a state of being installed vertically.

An inner tube 204 forming the process container is disposed inside the outer tube 203. The inner tube 204 is made of, for example, a heat resistant material such as quartz (SiO₂) or silicon carbide (SiC), and is formed in a cylindrical shape with its upper end closed and its lower end opened. The process container (reaction container) mainly includes the outer tube 203, the inner tube 204, and the manifold 209. A process chamber 201 is formed in a hollow cylindrical portion (inside the inner tube 204) of the process container.

The process chamber 201 is configured to be capable of accommodating wafers 200 as substrates in a state where the wafers 200 are arranged in a horizontal posture and in multiple stages in the vertical direction by a boat 217 which will be described later.

Nozzles 410 and 420 are provided in the process chamber 201 so as to penetrate a sidewall of the manifold 209 and the inner tube 204. Gas supply pipes 310 and 320 are connected to the nozzles 410 and 420, respectively. However, the process furnace 202 of the present embodiments is not limited to the above-described form.

Mass flow controllers (MFCs) 312 and 322, which are flow rate controllers (flow rate control parts), are installed on the gas supply pipes 310 and 320, respectively, sequentially from the upstream side. Further, valves 314 and 324, which are opening/closing valves, are installed on the gas supply pipes 310 and 320, respectively. Gas supply pipes 510 and 520 for supplying an inert gas are connected to the gas supply pipes 310 and 320 on the downstream side of the valves 314 and 324, respectively. MFCs 512 and 522, which are flow rate controllers (flow rate control parts), and valves 514 and 524, which are opening/closing valves, are provided in the gas supply pipes 510 and 520, respectively, sequentially from the upstream side.

The nozzles 410 and 420 are connected to the leading ends of the gas supply pipes 310 and 320, respectively. The nozzles 410 and 420 are configured as L-shaped nozzles, and their horizontal portions are formed so as to penetrate the sidewall of the manifold 209 and the inner tube 204. The vertical portions of the nozzles 410 and 420 are installed inside a channel-shaped (groove-shaped) preliminary chamber 201a, which is formed so as to protrude outward in the radial direction of the inner tube 204 and extends in the vertical direction of the inner tube 204, and are also installed in the preliminary chamber 201a to extend upward (upward in the arrangement direction of the wafers 200) along the inner wall of the inner tube 204.

The nozzles 410 and 420 are provided so as to extend from a lower region of the process chamber 201 to an upper region of the process chamber 201, and include a plurality of gas supply holes 410a and 420a, respectively, which are formed at positions facing the wafers 200, respectively. Thus, a process gas is supplied from the gas supply holes 410a and 420a of the respective nozzles 410 and 420 to the wafers 200, respectively. The plurality of gas supply holes 410a and 420a are formed over a region from a lower portion to an upper portion of the inner tube 204, have the same aperture area, and is installed at the same aperture pitch. However, the gas supply holes 410a and 420a are not limited to the above-described form. For example, the aperture area may be gradually increased from the lower portion to the upper portion of the inner tube 204. This makes it possible to make the flow rate of the gas supplied from the gas supply holes 410a and 420a more uniform.

The plurality of gas supply holes 410a and 420a of the nozzles 410 and 420 are formed at height positions from a lower portion to an upper portion of the boat 217, which will be described later. Therefore, the process gas supplied into the process chamber 201 from the gas supply holes 410a and 420a of the nozzles 410 and 420 is supplied to the entire region of the wafers 200 accommodated from the lower portion to the upper portion of the boat 217. The nozzles 410 and 420 are installed so as to extend from the lower region to the upper region of the process chamber 201, but may be installed so as to extend to the vicinity of the ceiling of the boat 217.

An inert gas is supplied from the gas supply pipe 310 into the process chamber 201 via the MFC 312, the valve 314, and the nozzle 410. Further, a precursor gas as a process gas is supplied from a container 14 into the process chamber 201 via a valve 316 and the gas supply pipe 310.

As a process gas, a reducing gas is supplied from the gas supply pipe 320 into the process chamber 201 via the MFC 322, the valve 324, and the nozzle 420.

As an inert gas, for example, a nitrogen (N₂) gas is supplied from the gas supply pipes 510 and 520 into the process chamber 201 via the MFCs 512 and 522, the valves 514 and 524, and the nozzles 410 and 420, respectively. Hereinafter, an example in which the N₂ gas is used as the inert gas will be described. However, as the inert gas, in addition to the N₂ gas, it may be possible to use, e.g., a rare gas such as an argon (Ar) gas, a helium (He) gas, a neon (Ne) gas, or a xenon (Xe) gas.

A process gas supply system mainly includes the gas supply pipes 310 and 320, the MFCs 312 and 322, the valves 314 and 324, and the nozzles 410 and 420. However, only the nozzles 410 and 420 may be considered as the process gas supply system. The process gas supply system may be simply referred to as a gas supply system. When a Mo-containing gas is allowed to flow from the gas supply pipe 310, a Mo-containing gas supply system mainly includes the gas supply pipe 310, the MFC 312, and the valve 314. However, it may be considered that the nozzle 410 is included in the Mo-containing gas supply system. Further, when the reducing gas is allowed to flow from the gas supply pipe 320, a reducing gas supply system mainly includes the gas supply pipe 320, the MFC 322, and the valve 324. However, it may be considered that the nozzle 420 is included in the reducing gas supply system. Further, an inert gas supply system mainly includes the gas supply pipes 510 and 520, the MFCs 512 and 522, and the valves 514 and 524.

A method of supplying a gas in the present disclosure is to transfer a gas via the nozzles 410 and 420 arranged in the preliminary chamber 201a in an annular vertically-elongated space defined by the inner wall of the inner tube 204 and the ends of a plurality of wafers 200. Then, the gas is injected into the inner tube 204 from the plurality of gas supply holes 410a and 420a formed the nozzles 410 and 420 at the positions facing the wafers 200. More specifically, the process gas or the like is injected in a direction parallel to the surfaces of the wafers 200 from the gas supply hole 410a of the nozzle 410 and the gas supply hole 420a of the nozzle 420.

An exhaust hole (exhaust port) 204a is a through-hole formed on a sidewall of the inner tube 204 at a position facing the nozzles 410 and 420. For example, the exhaust hole 204a is a slit-shaped through-hole elongated in the vertical direction. A gas supplied into the process chamber 201 from the gas supply holes 410a and 420a of the nozzles 410 and 420 and flowing on the surfaces of the wafers 200 flows into an exhaust passage 206 defined by a gap formed between the inner tube 204 and the outer tube 203 via the exhaust hole 204a. Then, the gas flowing into the exhaust passage 206 flows into an exhaust pipe 231 and is discharged to the outside of the process furnace 202.

The exhaust hole 204a is formed at a position facing the plurality of wafers 200, and a gas supplied from the gas supply holes 410a and 420a to the vicinity of the wafers 200 in the process chamber 201 flows in the horizontal direction and then flows into the exhaust passage 206 through the exhaust hole 204a. The exhaust hole 204a is not limited to the slit-shaped through-hole, but may be configured by a plurality of holes.

The exhaust pipe 231 for exhausting an internal atmosphere of the process chamber 201 is provided in the manifold 209. A pressure sensor 245, which is a pressure detector (pressure detecting part) for detecting an internal pressure of the process chamber 201, an auto pressure controller (APC) valve 243, and a vacuum pump 246 as a vacuum-exhausting device are connected to the exhaust pipe 231 sequentially from the upstream side. The APC valve 243 is configured to be capable of performing or stopping a vacuum exhaust in the process chamber 201 by opening or closing the valve while the vacuum pump 246 is actuated, and is also configured to be capable of adjusting the internal pressure of the process chamber 201 by adjusting an opening degree of the valve while the vacuum pump 246 is actuated. An exhaust system mainly includes the exhaust hole 204a, the exhaust passage 206, the exhaust pipe 231, the APC valve 243, and the pressure sensor 245. It may be considered that the vacuum pump 246 is included in the exhaust system.

A seal cap 219 serving as a furnace opening cover configured to hermetically seal a lower end opening of the manifold 209 is installed under the manifold 209. The seal cap 219 is configured to make contact with the lower end of the manifold 209 from the lower side in the vertical direction. The seal cap 219 is made of, for example, metal such as stainless steel (SUS), and is formed in a disk shape. An O-ring 220b as a seal member making contact with the lower end of the manifold 209 is installed on an upper surface of the seal cap 219. A rotator 267 for rotating the boat 217 in which the wafers 200 are accommodated is installed on the opposite side of the seal cap 219 from the process chamber 201. A rotary shaft 255 of the rotator 267 penetrates the seal cap 219 and is connected to the boat 217. The rotator 267 is configured to rotate the boat 217 to rotate the boat 217. The seal cap 219 is configured to be vertically moved up and down by a boat elevator 115 as an elevation mechanism vertically installed outside the outer tube 203. The boat elevator 115 is configured to be capable of loading/unloading the boat 217 into/from the process chamber 201 by moving the seal cap 219 up and down. The boat elevator 115 is configured as a transfer device (transfer system) which transfers the boat 217 and the wafers 200 accommodated in the boat 217 into/out of the process chamber 201.

The boat 217 serving as a substrate support is configured to arrange a plurality of wafers 200, for example, 25 to 200 wafers 200, in a horizontal posture and at intervals in the vertical direction with the centers of the wafers 200 aligned with one another. The boat 217 is made of, for example, a heat resistant material such as quartz or SiC. Heat insulating plates 218 made of, for example, a heat resistant material such as quartz or SiC, are installed in a horizontal posture in multiple stages (not shown) below the boat 217. This configuration makes it difficult to transfer heat from the heater 207 to the seal cap 219 side. However, the present embodiments are not limited to the above-described form. For example, instead of installing the heat insulating plates 218 below the boat 217, a heat insulating cylinder configured as a cylindrical member made of a heat resistant material such as quartz or SiC may be installed.

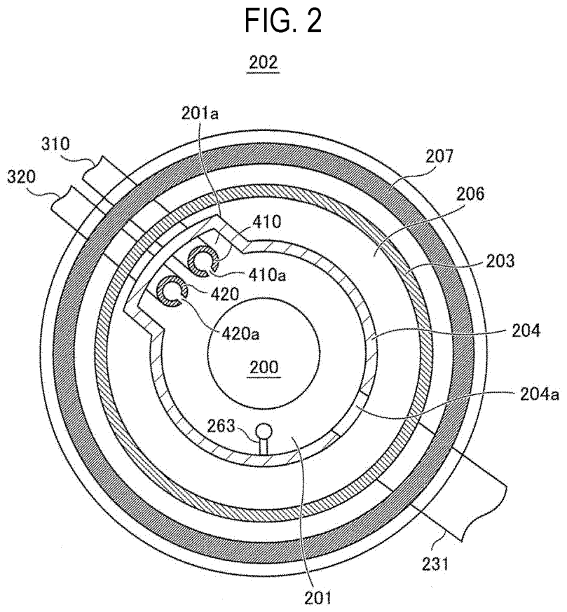

As shown in FIG. 2, a temperature sensor 263 serving as a temperature detector is installed in the inner tube 204. Based on temperature information detected by the temperature sensor 263, a supply amount of electricity to the heater 207 is adjusted such that the interior of the process chamber 201 has a desired temperature distribution. The temperature sensor 263 is configured as an L-shape, like the nozzles 410 and 420, and is installed along the inner wall of the inner tube 204.

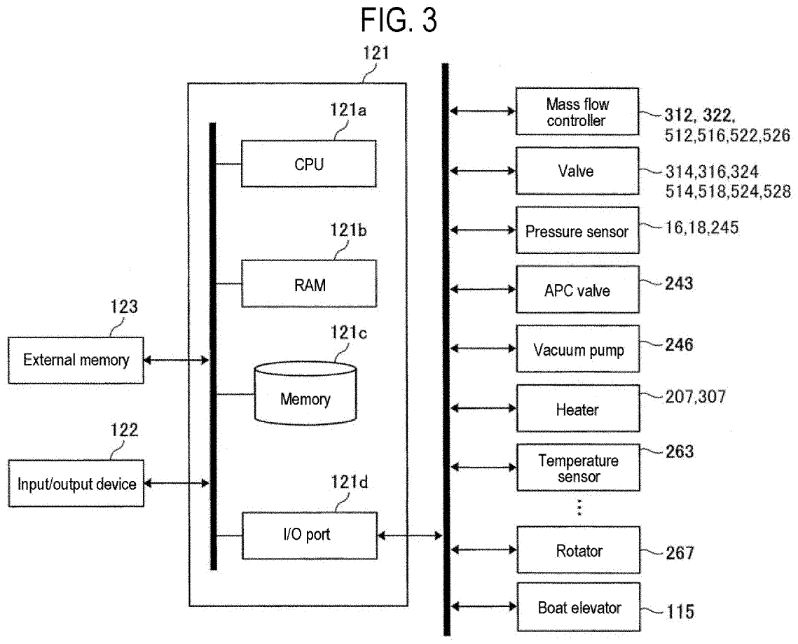

As shown in FIG. 3, a controller 121, which is a control part (control means), may be configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus. An input/output device 122 formed of, for example, a touch panel or the like, is connected to the controller 121.

The memory 121c is configured by, for example, a flash memory, a hard disk drive (HDD), or the like. A control program for controlling operations of a substrate processing apparatus and a process recipe in which sequences and conditions of a method of manufacturing a semiconductor device, which will be described later, are written, are readably stored in the memory 121c. The process recipe functions as a program for causing the controller 121 to execute each step in the method of manufacturing a semiconductor device, which will be described later, to obtain a predetermined result. Hereinafter, the process recipe and the control program may be generally and simply referred to as a “program.” When the term “program” is used herein, it may indicate a case of including the process recipe only, a case of including the control program only, or a case of including a combination of the process recipe and the control program. The RAM 121b is configured as a memory area (work area) in which a program or data read by the CPU 121a is temporarily stored.

The I/O port 121d is connected to the MFCs 312, 322, 516, 526, 512, and 522, the valves 314, 316, 324, 514, 518, 524, and 528, the pressure sensors 16, 18, and 245, and the like. The I/O port 121d is further connected to the APC valve 243, the vacuum pump 246, the heaters 207 and 307, the temperature sensor 263, the rotator 267, the boat elevator 115, and the like.

The CPU 121a is configured to read the control program from the memory 121c and execute the control program thus read. The CPU 121a is also configured to read the recipe from the memory 121c according to an input of an operation command from the input/output device 122. The CPU 121a is configured to control the flow rate adjustment operation of various kinds of gases by the MFCs 312, 322, 512, and 522, the opening/closing operation of the valves 314, 324, 514, and 524, and the like, according to contents of the read recipe thus read. The CPU 121a is further configured to control the opening/closing operation of the APC valve 243, the pressure adjusting operation performed by the APC valve 243 based on the pressure sensor 245, the temperature adjusting operation performed by the heater 207 based on the temperature sensor 263, the actuating and stopping of the vacuum pump 246, and the like. The CPU 121a is further configured to control the operation of rotating the boat 217 with the rotator 267 and adjusting the rotation speed of the boat 217, the operation of moving the boat 217 up and down by the boat elevator 115, the operation of accommodating the wafers 200 in the boat 217, and the like.

The controller 121 may be configured by installing, in the computer, the aforementioned program stored in an external memory (for example, a magnetic tape, a magnetic disk such as a flexible disk or a hard disk, an optical disk such as a CD or a DVD, a magneto-optical disc such as an MO, or a semiconductor memory such as a USB memory or a memory card) 123. The memory 121c and the external memory 123 are configured as a non-transitory computer-readable recording medium. Hereinafter, the memory 121c and the external memory 123 may be generally and simply referred to as a “recording medium.” When the term “recording medium” is used herein, it may indicate a case of including the memory 121c only, a case of including the external memory 123 only, or a case of including both the memory 121c and the external memory 123. The program may be provided to the computer using a communication means such as the Internet or a dedicated line, instead of using the external memory 123.

### (2) Configuration of Gas Supply System

Next, the gas supply system (the precursor gas supply system) according to the present embodiments will be specifically described. As shown in FIG. 1, the precursor gas supply system 12 includes a container 14, the gas supply pipe 310 as a first pipe, a second pipe 515, a third pipe 525, a first pressure measurer 16, and a second measurer 18, and a controller 121 as a control part.

### (Precursor)

In the present embodiments, a precursor is a material having a vapor pressure characteristic of being a saturated vapor pressure of 0.01 to 100 KPa at 50 degrees C. to 200 degrees C. More desirably, it is a material having a low vapor pressure characteristic of being a saturated vapor pressure of 0.01 to 5 KPa at 50 degrees C. to 200 degrees C. The material having such a characteristic of relatively low vapor pressure is called a low vapor pressure material (low vapor pressure precursor). In the present disclosure, the precursor existing in the container 14 may be a solid, a liquid, or a gas. In addition, the precursor may be a solid-state material in a solid state and also a low vapor pressure material at normal temperature and normal pressure.

The precursor may be, for example, a material containing a metal element and a halogen element. The metal element is selected from, for example, Al, Mo, W, Hf, Zr, and the like. The halogen element is selected from F, Cl, Br, I, and the like. Examples of the precursor that is a solid at normal temperature and normal pressure may include AlCl₃, Al₂Cl₆, MoCl₅, WCl₆, HfCl₄, ZrCl₄, MoO₂Cl₂, MoOCl₄, and the like. The precursor that is a liquid at normal temperature and normal pressure is, for example, a precursor of a metal element such as Ru, La or the like.

### (Container)

The precursor is stored inside the container 14. The container 14 is configured to vaporize or sublimate the precursor to generate a precursor gas. In the present disclosure, the phase change of a precursor into a vapor is not separately referred to as “vaporization or sublimation” for convenience of explanation, and is simply referred to as “vaporization” unless otherwise specified.

The heater 307 is installed in the container 14, and the temperature of the container 14 is adjusted by the heater 307 to control a vaporization amount of the precursor. The temperature of the container 14 may be changed for each substrate processing. Further, the valve 316 is installed between the container 14 and a joining portion of the gas supply pipe 310 and the gas supply pipe 510.

### (First Pipe)

The gas supply pipe 310 corresponding to the first pipe of the present disclosure is connected between the container 14 and the process chamber 201, and has a straight pipe portion SR. The straight pipe portion SR of the present embodiments has a straight cylindrical shape. In the present disclosure, the straight pipe portion SR is not limited to the straight cylindrical shape, but may have, for example, a right-angled cylindrical shape having a triangular or square bottom surface. A method of calculating a pressure loss will be described later.

The straight pipe portion SR includes a first position B1 and a second position B2 at both ends in the axial direction of the pipe. The second position B2 is located at a certain interval on a further downstream side of the flow of the precursor gas than the first position B1. The interval can be set appropriately, and in the present embodiments, it is, for example, 500 mm. The first pressure measurer 16 is installed at the first position B1 of the straight pipe portion SR. Further, the second pressure measurer 18 is installed at the second position B2 of the straight pipe portion SR. Although not shown, a pipe heater and a heat insulating material are wound around the straight pipe portion SR. The heat insulating material keeps the temperature of the precursor gas constant in the straight pipe portion SR with respect to the direction of a gas flow.

In the present embodiments, a pressure loss between the first position B1 and the second position B2 in the straight pipe portion SR is configured as a predetermined pressure loss so as to be capable of calculating the flow rate of the precursor gas flowing inside the straight pipe portion SR. In the present embodiments, “configured as a predetermined pressure loss” specifically means a pressure loss generated due to friction generated between the precursor gas and an inner wall surface.

Therefore, in the present embodiments, a member such as an orifice or a valve is not installed in a portion where the pressure loss is measured. In addition, a bent portion such as an elbow, a throttle portion, or the like is not formed. That is, inside the straight pipe portion SR, since a change in the inner diameter of a flow path, the bending of the flow path, etc. are not made, a pressure loss other than the friction generated between the precursor gas and the inner wall surface is set to “0.”.

### (Second Pipe)

The second pipe 515 is a pipe that is branches from the gas supply pipe 510, and is connected to the container 14 to supply a first inert gas to the container 14. The first inert gas supplier 516 and the valve 518 for supplying the first inert gas are installed on the second pipe 515. The first inert gas is, for example, Ar or N₂, and promotes the vaporization of the precursor. By adjusting the supply of the first inert gas, it is possible to adjust the vaporization amount of the precursor.

### (First Inert Gas Supplier)

The first inert gas supplier 516 may be configured as a flow rate controller or a flow rate measurer so as to be capable of measuring the flow rate of the first inert gas flowing via the second pipe 515. The flow rate controller is, for example, an MFC (Mass Flow Controller), and the flow rate measurer is, for example, an MFM (Mass Flow Meter). It may be considered that the first inert gas supplier includes not only the MFC or MFM but also a part or all of the inert gas supply system.

The first inert gas supplier 516 supplies the first inert gas to the container 14 via the second pipe 515. The temperature of the container 14 is kept constant while the first inert gas is supplied to the container 14. When the first inert gas is supplied, a vaporized precursor as a first precursor gas and the first inert gas are mixed in the container 14. The mixed gas is generated as a second precursor gas and sent out from the container 14 to the downstream side. In the present disclosure, the second pipe 515, the first inert gas supplier 516, and the valve 518 are not essential.

### (Third Pipe)

The third pipe 525 is a pipe that branches from the gas supply pipe 520, and is connected to the gas supply pipe 310 to supply a second inert gas to the gas supply pipe 310. The second inert gas supplier 526 and the valve 528 for supplying the second inert gas are installed on the third pipe 525.

### (Second Inert Gas Supplier)

The second inert gas supplier 526 may be configured as a flow rate controller or a flow rate measurer so as to be capable of measuring the flow rate of the second inert gas flowing via the third pipe 525. The flow rate controller is, for example, an MFC, and the flow rate measurer is, for example, an MFM. The second inert gas is, for example, Ar or N₂, which is used to dilute the precursor gas. It may considered that the second inert gas supplier includes not only the MFC or MFM but also a part or all of the inert gas supply system.

By supplying the second inert gas, the second inert gas is further mixed with the second precursor gas that is the mixed gas sent out from the container 14. Then, the mixed gas containing the vaporized precursor, the first inert gas, and the second inert gas is sent out to the straight pipe portion SR of the gas supply pipe 310, as a third precursor gas. In the present disclosure, the third pipe 525, the second inert gas supplier 526, and the valve 528 are not essential.

### (Pressure Measurer)

The first pressure measurer 16 and the second pressure measurer 18 are installed in series along the gas supply pipe 310. The first pressure measurer 16 measures the pressure of the precursor gas at the first position B1. The second pressure measurer 18 measures the pressure of the precursor gas at the second position B2. The first pressure measurer 16 and the second pressure measurer 18 are, for example, pressure sensors. A measurement signal from the first pressure measurer 16 and a measurement signal from the second pressure measurer 18 are input to the controller 121. In the present disclosure, the measurement signals are not limited to numerical values of the pressure itself (pressure values). The measurement signals may be, for example, digital signals including a combination of numerical values and symbols set by the pressure measurers, corresponding to the numerical values of the pressure itself. In the present disclosure, any measurement signal can be adopted as long as it is a signal that is capable of calculating a pressure loss.

In the present embodiments, both the first pressure measurer 16 and the second pressure measurer 18 are configured by an absolute pressure gauge. That is, the measurement signal of the present embodiments is a value of the absolute pressure. When the absolute pressure gauge is used, for example, vacuumization can be performed with a pump, and the state of 0 (zero) Pa can be stored as a virtual zero point of the pressure gauge, having no fluid molecule. In the present disclosure, the pressure gauge is not limited to the absolute pressure gauge, and any other pressure gauge such as a pressure gauge that measures a gauge pressure based on the atmospheric pressure can be used.

### (Control Part)

The controller 121 corresponding to the control part of the present disclosure calculates the pressure loss between the first position B1 and the second position B2 from the measurement signal from the first pressure measurer 16 and the measurement signal from the second pressure measurer 18. The controller 121 is configured to be capable of calculating the flow rate of the precursor gas (the third precursor gas) based on the calculated pressure loss.

### (3) Substrate Processing Process

Next, as a substrate processing process, a process of manufacturing a semiconductor device using the substrate processing apparatus 10 according to the present embodiments will be described. In the following, the outline of the process of manufacturing a semiconductor device will be described first, and the part related to a precursor gas supply method using the precursor gas supply system 12 in the process of manufacturing a semiconductor device will be described in “(4) Precursor Gas Supplying Method.”

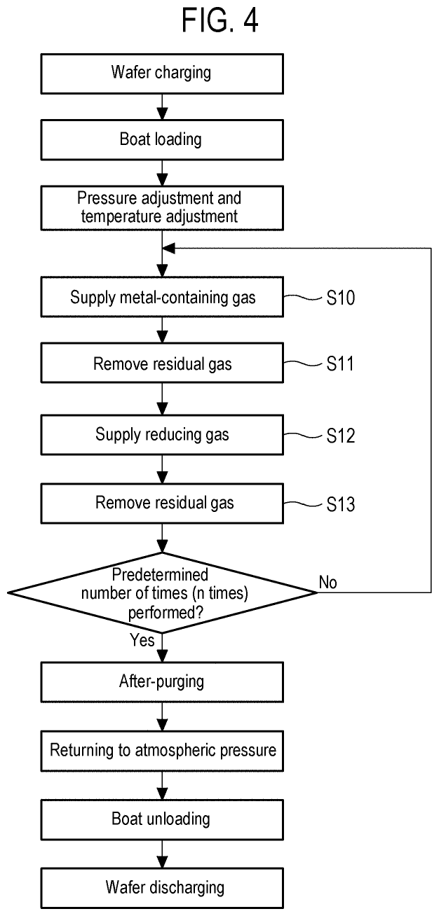

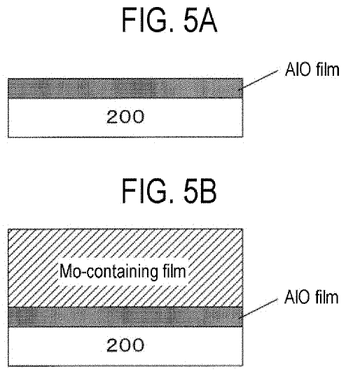

As a process of manufacturing a semiconductor device, an example of forming a Mo-containing film containing molybdenum (Mo), which is used as, for example, a control gate electrode of 3D NAND, on a wafer 200 will be described with reference to FIGS. 4, 5A, and 5B. Here, as shown in FIG. 5A, the wafer 200 having a surface on which an aluminum oxide (AlO) film that is a metal oxide film as well as a metal-containing film containing aluminum (Al) that is a non-transition metal element is formed, is used. Then, as shown in FIG. 5B, a Mo-containing film is formed on the wafer 200 on which the AlO film is formed, by a substrate processing process to be described later. A step of forming the Mo-containing film is performed using the process furnace 202 of the above-described substrate processing apparatus 10. In the following description, the operation of each part constituting the substrate processing apparatus 10 is controlled by the controller 121.

When the term “wafer” is used in the present disclosure, it may refer to “a wafer itself” or “a wafer and a laminated body of certain layers or films formed on a surface of a wafer.” When the phrase “a surface of a wafer” is used in the present disclosure, it may refer to “a surface of a wafer itself” or “a surface of a certain layer or film formed on a wafer”. When the term “substrate” is used in the present disclosure, it may be synonymous with the term “wafer.”

### (Wafer Loading)

When a plurality of wafers 200 are charged into the boat 217 (wafer charging), as shown in FIG. 1, the boat 217 supporting the plurality of wafers 200 is lifted up by the boat elevator 115 and is loaded into the process chamber 201 (boat loading) and arranged in the process container. In this state, the seal cap 219 seals the lower end of the outer tube 203 via the O-ring 220.

### (Pressure Adjustment and Temperature Adjustment)

The interior of the process chamber 201, that is, a space where the wafer 200 is placed, is vacuum-exhausted by the vacuum pump 246 to reach a desired pressure (degree of vacuum). At this time, the internal pressure of the process chamber 201 is measured by the pressure sensor 245. The APC valve 243 is feedback-controlled based on the measured pressure information (pressure adjustment). The vacuum pump 246 always keeps in operation at least until processing on the wafers 200 is completed.

Further, the interior of the process chamber 201 is heated by the heater 207 to a desired temperature. At this time, a supply amount of electricity to the heater 207 is feedback-controlled based on the temperature information detected by the temperature sensor 263 such that the interior of the process chamber 201 has a desired temperature distribution (temperature adjustment). In the following, the temperature of the heater 207 is set to a temperature such that the temperature of the wafer 200 is within a range of, for example, 300 degrees C. or higher and 600 degrees C. or lower. Heating the interior of the process chamber 201 by the heater 207 is continuously performed at least until the processing on the wafers 200 is completed.

### [Step S10] (Metal-Containing Gas Supply)

The valve 314 is opened to allow an inert gas to flow into the container 14. Further, the valve 316 is opened to allow a metal-containing gas, which is a precursor gas, to flow from the container 14 into the gas supply pipe 310. The flow rate of the metal-containing gas is adjusted by the flow rate of the inert gas adjusted by the MFC 312, and the metal-containing gas is supplied into the process chamber 201 from the gas supply hole 410a of the nozzle 410 and is exhausted from the exhaust pipe 231. In this operation, the metal-containing gas is supplied to the wafer 200. At the same time, the valve 514 is opened to allow an inert gas to flow into the gas supply pipe 510. The flow rate of the inert gas flowing in the gas supply pipe 510 is adjusted by the MFC 512, and the inert gas is supplied into the process chamber 201 together with the metal-containing gas and is exhausted from the exhaust pipe 231. At this time, in order to prevent the metal-containing gas from entering the nozzle 420, the valve 524 is opened to allow an inert gas to flow into the gas supply pipe 520. The inert gas is supplied into the process chamber 201 via the gas supply pipe 320 and the nozzle 420 and is exhausted from the exhaust pipe 231.

At this time, the APC valve 243 is adjusted so that the internal pressure of the process chamber 201 is, for example, a pressure within a range of 1 to 3,990 Pa, for example, 1,000 Pa. The supply flow rate of the inert gas controlled by the MFC 312 is, for example, a flow rate within a range of 0.1 to 1.0 slm, specifically 0.1 to 0.5 slm. The supply flow rate of the inert gas controlled by the MFCs 512 and 522 is, for example, a flow rate within a range of 0.1 to 20 slm. The notation of a numerical range such as “1 to 3,990 Pa” in the present disclosure means that the lower limit value and the upper limit value are included in the range. Therefore, for example, “1 to 3,990 Pa” means “1 Pa or more and 3,990 Pa or less.” The same applies to other numerical ranges.

At this time, the only gases flowing in the process chamber 201 are the metal-containing gas and the inert gas. Here, a molybdenum (Mo)-containing gas can be used as the metal-containing gas. Examples of the Mo-containing gas may include a MoCl₅ gas, a MoO₂Cl₂ gas, and a MoOCl₄ gas. By supplying the metal-containing gas, a metal-containing layer is formed on the wafer 200 (the AlO film which is a base film of the surface). Here, when either the MoO₂Cl₂ gas or the MoOCl₄ gas is used as the metal-containing gas, the metal-containing layer is a Mo-containing layer. The Mo-containing layer may be a Mo layer containing Cl or O, an adsorption layer of MoO₂Cl₂ (MoOCl₄), or both of them. The Mo-containing layer is a film containing Mo as a main component and a film which may contain elements such as Cl, O, and H in addition to the Mo element.

### [Step S11 (First Purging Step)]

### (Residual Gas Removal)

After a predetermined time has elapsed from the start of the supply of the metal-containing gas, for example, after 0.01 to 10 seconds, the valve 316 (the valve 314) of the gas supply pipe 310 is closed to stop the supply of the metal-containing gas. That is, the time for supplying the metal-containing gas to the wafer 200 is, for example, a time within a range of 0.01 to 10 seconds. At this time, with the APC valve 243 of the exhaust pipe 231 left open, the interior of the process chamber 201 is vacuum-exhausted by the vacuum pump 246 to exclude an unreacted metal-containing gas or a metal-containing gas that has contributed to the formation of the metal-containing layer, which remains in the process chamber 201, from the process chamber 201. That is, the interior of the process chamber 201 is purged. At this time, the valves 514 and 524 are left open to maintain the supply of the inert gas into the process chamber 201. The inert gas acts as a purge gas, which can enhance the effect of excluding the unreacted metal-containing gas or the metal-containing gas that has contributed to the formation of the metal-containing layer, which remains in the process chamber 201, from the process chamber 201.

### [Step S12]

### (Reducing Gas Supply)

After removing the residual gas in the process chamber 201, the valve 324 is opened to allow a reducing gas to flow into the gas supply pipe 320. The flow rate of the reducing gas is adjusted by the MFC 322, and the reducing gas is supplied into the process chamber 201 from the gas supply hole 420a of the nozzle 420 and is exhausted from the exhaust pipe 231. In this operation, the reducing gas is supplied to the wafer 200. At the same time, the valve 524 is opened to allow an inert gas to flow into the gas supply pipe 520. The flow rate of the inert gas flowing in the gas supply pipe 520 is adjusted by the MFC 522. The inert gas is supplied into the process chamber 201 together with the reducing gas and is exhausted from the exhaust pipe 231. At this time, in order to prevent the reducing gas from entering the nozzle 410, the valve 514 is opened to allow an inert gas to flow into the gas supply pipe 510. The inert gas is supplied into the process chamber 201 via the gas supply pipe 310 and the nozzle 410, and is exhausted from the exhaust pipe 231.

At this time, the APC valve 243 is adjusted so that the internal pressure of the process chamber 201 is, for example, a pressure within a range of 1 to 3,990 Pa, for example, 2,000 Pa. The supply flow rate of the reducing gas controlled by the MFC 322 is, for example, a flow rate within a range of 1 to 50 slm, specifically 15 to 30 slm. The supply flow rate of the inert gas controlled by the MFCs 512 and 522 is, for example, a flow rate within a range of 0.1 to 30 slm. The time for supplying the reducing gas to the wafer 200 is, for example, a time within a range of 0.01 to 120 seconds.

At this time, the only gases flowing in the process chamber 201 are the reducing gas and the inert gas. Here, for example, a hydrogen (H₂) gas, a deuterium (D2) gas, a gas containing activated hydrogen, or the like can be used as the reducing gas. When the H₂ gas is used as the reducing gas, the H₂ gas undergoes a substitution reaction with at least a portion of the Mo-containing layer formed on the wafer 200 in step S10. That is, O or chlorine (Cl) in the Mo-containing layer reacts with H₂ to be desorbed from the Mo-containing layer, and is discharged from the process chamber 201, as reaction by-products such as water vapor (H₂O), hydrogen chloride (HCl), or chlorine (Cl₂). Then, a metal layer (Mo layer) containing Mo and substantially free of Cl and O is formed on the wafer 200.

### [Step S13 (Second Purging Step)]

### (Removal of Residual Gas)

After forming the metal layer, the valve 324 is closed to stop the supply of reducing gas.

Then, an unreacted reducing gas or a reducing gas that has contributed to the formation of the metal layer, and reaction by-products, which remain in the process chamber 201, are excluded from the process chamber 201 according to the same processing procedure as in the above-described step S11 (the first purging step). That is, the interior of the process chamber 201 is purged.

### (Performing Predetermined Number of Times)

By performing a cycle once or more (predetermined number of times (n times), the cycle including sequentially performing the above-described steps S10 to S13, a metal-containing film having a predetermined thickness (for example, 0.5 to 20.0 nm) is formed on the wafer 200. The above cycle may be repeated multiple times. Further, each of the steps S10 to S13 may be performed at least once or more.

### (After-Purging and Returning to Atmospheric Pressure)

An inert gas is supplied into the process chamber 201 from each of the gas supply pipes 510 and 520 and is exhausted from the exhaust pipe 231. The inert gas acts as a purge gas, whereby the interior of the process chamber 201 is purged with the inert gas to remove a gas and reaction by-products remaining in the process chamber 201 from the process chamber 201 (after-purging). After that, the internal atmosphere of the process chamber 201 is substituted with the inert gas (inert gas substitution), and the internal pressure of the process chamber 201 is returned to the atmospheric pressure (returning to atmospheric pressure).

### (Wafer Unloading)

After that, the seal cap 219 is moved down by the boat elevator 115 to open the lower end of the outer tube 203. Then, the processed wafers 200 supported by the boat 217 are unloaded from the lower end of the outer tube 203 to the outside of the outer tube 203 (boat unloading). After that, the processed wafers 200 are discharged from the boat 217 (wafer discharging).

### (4) Method of Supplying Precursor Gas

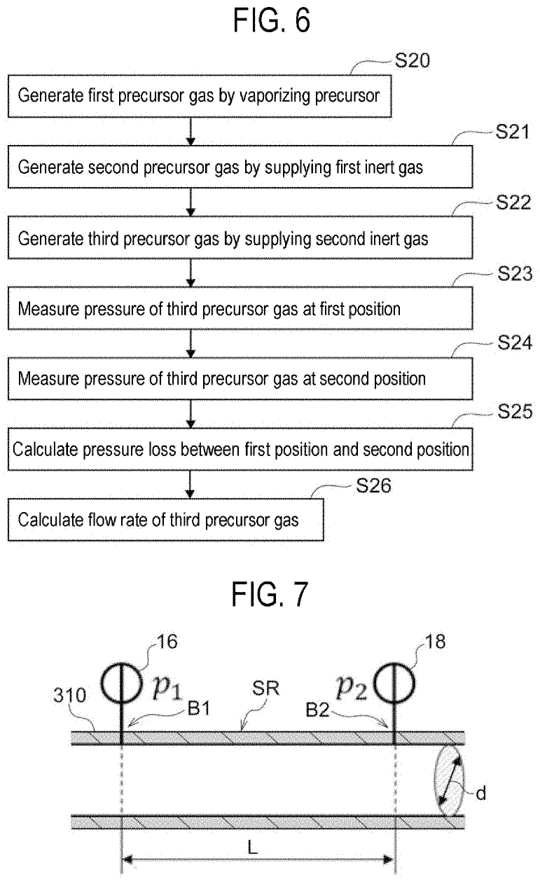

Next, a method of supplying the precursor gas, which is performed by using the precursor gas supply system 12 according to the present embodiments, will be specifically described with reference to FIGS. 6, 7, 8A, and 8B. The method of supplying the precursor gas is performed in step S10 in FIG. 4 during a step of supplying the metal-containing gas as the precursor gas to the process chamber 201 that is a reaction chamber.

First, as shown in step S20 in FIG. 6, the first precursor gas is generated by vaporizing the precursor in the container 14. Next, as shown in step S21, the vaporization of the precursor is promoted by supplying the first inert gas to the container 14. That is, the second precursor gas in which the first precursor gas and the first inert gas are mixed is generated. Then, the second precursor gas is allowed to flow to the downstream side of the container 14.

Next, as shown in step S22, the second precursor gas is diluted by supplying the second inert gas to the gas supply pipe 310. In the present embodiments, the same type of gas, for example, an N₂ gas, is used as the first inert gas and the second inert gas. That is, the third precursor gas that mixes the second precursor gas and the second inert gas is generated. The generated third precursor gas flows in the straight pipe portion SR.

Next, as shown in step S23, the pressure of the third precursor gas at the first position B1 of the straight pipe portion SR is measured, and as shown in step S24, the pressure of the third precursor gas at the second position B2 of the straight pipe portion SR is measured. The measured pressure value at the first position B1 and the measured pressure value at the second position B2 are input to the controller 121.

Next, as shown in step S25, a pressure loss Δp between the first position B1 and the second position B2 is calculated from the pressure at the first position B1 and the pressure at the second position B2.

### <Processing of Calculating Flow Rate of Precursor Gas>

Next, as shown in step S26, the flow rate of the third precursor gas flowing in the straight pipe portion SR is calculated based on the calculated pressure loss Δp. In addition, the flow rate and concentration of the first precursor gas are calculated.

Specifically, first, as shown in FIG. 7, a proportional relationship shown in the following equation (1) is established between the flow rate Qₘᵢₓ of a fluid flowing in the straight pipe portion SR and the pressure loss Δp that is a differential pressure between the pressure p1 at the first position B1 and the pressure p2 at the second position B2. The equation (1) is based on the Hagen-Poiseuille's equation.

$$\begin{matrix}[ Eq . 1 ] & \\ {Q}_{mix} = \frac{π {d}^{4}}{128 {μ}_{mix}} \frac{Δ p}{L} & ( 1 )\end{matrix}$$

Here, d is an inner diameter of the pipe of the straight pipe portion SR. L is a distance between the first position B1 and the second position B2. π is a circumference ratio. d, L, and it are all known constants.

μmix is a viscosity coefficient of the third precursor gas containing the first precursor gas, which is a film-forming precursor, the first inert gas, which is a carrier gas for promoting vaporization, and the second inert gas, which is a dilution gas. μₘᵢₓ is an unknown number that changes depending on the concentration of each contained gas. Qₘᵢₓ is a volumetric flow rate of the third precursor gas. The equation 1 may be calculated by appropriately adding a correction coefficient. It is possible to improve the calculation accuracy through the calculation by adding the correction coefficient.

In the present embodiments, the first inert gas and the second inert gas are the same type of gas. Further, since the flow rates of the first inert gas and the second inert gas are controlled by MFC, the values of the respective flow rates can be obtained. Therefore, the concentration of the first precursor gas, which is the vaporized precursor, can be calculated with respect to the third precursor gas which is a mixture of the first precursor gas, the first inert gas, and the second inert gas.

Next, it is assumed that the molar concentration of the first precursor gas is x₁ and the molar concentration of a gas corresponding to the sum of the first inert gas and the second inert gas is x₂ (x₂=1−x₁). Further, it is assumed that the viscosity coefficients when the respective gases exist alone are μ₁ and μ₂. At this time, the viscosity coefficient μₘᵢₓ of the third precursor gas that mixes the first precursor gas, the first inert gas, and the second inert gas is expressed by the following equations (2) and (3).

$${μ}_{mix} = \frac{{x}_{1} {μ}_{1}}{{x}_{1} + {ϕ}_{12} {x}_{2}} + \frac{{x}_{2} {μ}_{2}}{{x}_{2} + {ϕ}_{21} {x}_{1}} \qquad ( 2 )$$

$${ϕ}_{ij} = \frac{{[ 1 + \sqrt{{μ}_{i} / {μ}_{j}} {( {M}_{j} / {M}_{i} )}^{\frac{1}{4}} ]}^{2}}{\sqrt{8 ( 1 + {M}_{j} / {M}_{i} )}} , \\ ( i , j ) = ( 1 , 2 ) \cdot ( 2 , 1 ) \qquad ( 3 )$$

Here, M₁ and M₂ are the molecular weights (molar masses) of the first precursor gas and the gas corresponding to the sum of the first inert gas and the second inert gas, respectively. Further, the state of (Ts, Ps)=(273.15K, 101,325 Pa) is called a standard state. Further, assuming that the volumetric flow rates of the third precursor gas, the first precursor gas, and the gas corresponding to the sum of the first inert gas and the second inert gas in the standard state is Q′ₘᵢₓ, Q′₁, and Q′₂, the following relational expressions (4) and (5) are established.

Q′ₘᵢₓ=Q′₁+Q′₂ (4)

Q′₁=x₁Q′ₘᵢₓQ′₂=x₂Q′ₘᵢₓ (5)

Of the variables in the equations (4) and (5), the variable with a′ (dash) on the right shoulder means the flow rate in a unit of [SLM] or [SCCM]. The relationship of the following equation (6) is established between the flow rate Q at an arbitrary temperature T and pressure p and the flow rate Q′ in the standard state.

$${Q}^{′} = Q \cdot \frac{p}{{p}_{s}} \cdot \frac{{T}_{s}}{T} \qquad ( 6 )$$

Here, the temperature T and the pressure p are equal to the temperature and the average pressure of the straight pipe portion SR, respectively, and both are measurable values. In the above equations (1) to (6), the independent unknowns are the flow rates Qₘᵢₓ and x₂. The solutions of the unknowns can be obtained by performing iterative calculation by a dichotomy method.

The flow rate and concentration of the first precursor gas are calculated by the above calculation. It should be noted that at least one selected from the group of a molar concentration, a viscosity coefficient, a molecular weight, and a vapor pressure characteristic of each of the first precursor gas and the gas corresponding to the sum of the first inert gas and the second inert gas, corresponds to the “characteristics of gas” of the present disclosure.

### <Control Operation Based on Calculation Result>

The controller 121 is configured to be capable of controlling the first inert gas supplier 516 based on the calculated flow rate of the first precursor gas and adjusting the flow rate of the first inert gas to be supplied to the container 14 under the control of the first inert gas supplier 516.

Further, the controller 121 is configured to be capable of controlling the second inert gas supplier 526 based on the calculated flow rate of the first precursor gas and adjusting the flow rate of the second inert gas to be supplied to the gas supply pipe 310 under the control of the second inert gas supplier 526.

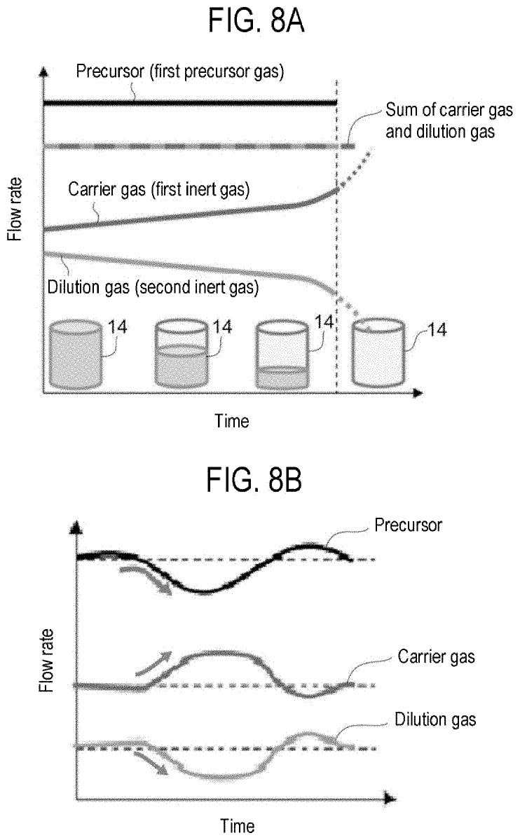

FIG. 8A exemplifies a change in the flow rate of each of the precursor as the first precursor gas, the carrier gas as the first inert gas, and the dilution gas as the second inert gas, which is set in the substrate processing, over time. The flow rate of the first precursor gas in the container 14 is constant over time. Further, the flow rate of the gas corresponding to the sum of the first inert gas and the second inert gas is also constant over time. Further, the flow rate of the first inert gas gradually increases over time, and the flow rate of the second inert gas gradually decreases over time.

Further, FIG. 8B exemplifies a change in the flow rate of each of the first precursor gas, the first inert gas, and the second inert gas, which is controlled based on the calculated flow rate of the first precursor gas, over time.

As shown in FIG. 8B, in the present embodiments, when a decrease in the flow rate of the first precursor gas is detected by calculation, the controller 121 increases the flow rate of the first inert gas so as to keep the total flow rate of the third precursor gas to be supplied to the process chamber 201 constant. Further, when the flow rate of the first inert gas is increased, the controller 121 decreases the flow rate of the second inert gas so as to keep the concentration of the first precursor gas in the third precursor gas to be supplied to the process chamber 201 constant.

Further, when an increase in the flow rate of the first precursor gas is detected by calculation, the controller 121 decreases the flow rate of the first inert gas so as to keep the total flow rate of the third precursor gas to be supplied to the process chamber 201 constant. Further, when the flow rate of the first inert gas is decreased, the controller 121 increases the flow rate of the second inert gas so as to keep the concentration of the first precursor gas in the third precursor gas constant. That is, in the present embodiments, all of the flow rate of the first precursor gas, the flow rate of the second precursor gas, and the flow rate of the third precursor gas are controlled based on the calculation result. Further, the concentration of the first precursor gas in the second precursor gas or the third precursor gas is also controlled.

### (5) Effects of Present Embodiments

In the present embodiments, the gas supply pipe 310 includes the straight pipe portion SR, and the pressure loss between the first position B1 at the upstream side and the second position B2 at the downstream side in the straight pipe portion SR is configured with a predetermined pressure loss so as to be capable of calculating the flow rate of the precursor gas flowing inside the straight pipe portion SR.

Further, the flow rate of the precursor gas is calculated by using, for example, the proportional relationship between the volume flow rate and the pressure loss, which is defined by the Hagen-Poiseuille's equation. Then, by using the comparison result between the calculated flow rate of the precursor gas and the flow rate of the precursor gas which is set for the substrate processing, it is possible to adjust the subsequent precursor gas supply process so that the set flow rate is achieved.

Here, in the present embodiments, a portion between the first position B1 and the second position B2, which is a portion where the pressure loss is measured in the gas supply pipe 310, is a simple straight pipe portion SR. Therefore, the pressure loss measured between the first position B1 and the second position B2 is only the pressure loss due to the friction between the precursor gas and the inner wall surface of the gas supply pipe 310 when the precursor gas passes through the inside of the gas supply pipe 310. Therefore, in the present embodiments, the configuration of the precursor gas supply system 12 can be simplified, and as a result, the accuracy of pressure measurement for controlling the flow rate of the precursor gas can be improved. Therefore, according to the present embodiments, the flow rate of the precursor gas can be appropriately controlled even with a simple configuration.

In general, an MFC is often used to control the flow rate of the precursor gas. However, in the case of the flow rate control by the MFC, since the pressure loss of a fluid in the MFC becomes large, it is necessary to increase the pressure inside the pipe on the upstream side of the MFC in order to perform appropriate control. On the other hand, at present, in the precursor gas supply system 12 of the substrate processing apparatus, the types of precursors are diversified. For example, a material that is vaporized at a relatively low vapor pressure (low vapor pressure precursor), such as HfCl₄ or ZrCl₄, may be used as the precursor.

When the precursor gas is the low vapor pressure precursor gas and the MFC is arranged on the downstream side of the flow of the precursor gas, the partial pressure of the precursor in the low vapor pressure precursor gas in a pipe on the upstream side of the MFC may exceed a saturated vapor pressure. In this case, there is a problem that it does not flow at a required flow rate. In addition, the low vapor pressure precursor exceeding the saturated vapor pressure may be solidified or liquefied.

As an example of a flow rate control method capable of suppressing the pressure loss to a small value, for example, a method using an infrared (IR) sensor can be considered. However, the IR sensor has a problem that the cost increases. In addition, since regular maintenance is required, there is also a problem that the burden of maintenance increases.

Here, in the present embodiments, the precursor gas is generated by vaporizing the low vapor pressure precursor in a solid state. In the present embodiments, even when the precursor gas is vaporized from the low vapor pressure precursor, the flow rate of the precursor gas can be appropriately controlled without requiring the MFC, so that it is capable of suppressing that it does not flow at a required flow rate as in the case of using the MFC. That is, it is possible to allow a gas having a large flow rate to stably flow as compared with the MFC. Further, in the present embodiments, since the flow rate of the precursor gas can be appropriately controlled with a simple configuration, a complicated structure such as the IR sensor is not required. Therefore, the present embodiments are particularly effective when the precursor gas is generated using the low vapor pressure precursor.

Further, in the present embodiments, since the flow rate of the first precursor gas, which is a vaporized precursor, is calculated, the feedback control in the precursor gas supply process can be appropriately performed.

Further, in the present embodiments, since the concentration of the first precursor gas is also calculated in addition to the flow rate of the first precursor gas, the feedback control in the precursor gas supply process can be performed more appropriately.

Further, in the present embodiments, both the first pressure measurer 16 and the second pressure measurer 18 are configured by the absolute pressure gauge. Here, for example, when a task of converting the volume flow rate to the mass flow rate occurs, such as the calculation of the precursor gas flow rate of the low vapor pressure precursor, the average value of the absolute pressure may be required in the conversion. Therefore, the measurement of the pressure by the absolute pressure gauge is advantageous in that the calculation accuracy of the precursor gas flow rate can be improved.

Further, in the present embodiments, when a change of the increase/decrease in the flow rate of the first precursor gas is detected by the calculation, the controller 121 increases or decreases the flow rate of the first inert gas so as to keep the total flow rate of the third precursor gas to be supplied to the process chamber 201 constant. Therefore, since the supply amount of the third precursor gas per unit time can be kept constant, it is possible to prevent a shortage of the third precursor gas required for substrate processing.

Further, in the present embodiments, when the flow rate of the first inert gas is increased or decreased, the controller 121 increases or decreases the flow rate of the second inert gas so as to keep the concentration of the first precursor gas in the third precursor gas constant. Therefore, it is possible to make the variation in film formation quality in the substrate processing constant.

Further, with the substrate processing apparatus 10 provided with the precursor gas supply system 12 according to the present embodiments, the substrate processing apparatus 10 can be easily configured, and the quality of a substrate can be improved by using the third precursor gas whose flow rate is appropriately controlled.

Similarly, with the semiconductor device manufacturing method using the substrate processing apparatus 10 provided with the precursor gas supply system 12 according to the present embodiments, a semiconductor device with improved quality can be manufactured by using the precursor gas whose flow rate is appropriately controlled.

Further, in the precursor gas supply system 12 according to the present embodiments, a program that causes, by a computer, the controller 121 to execute a series of processes for performing the precursor gas supply method may be created. The created program can be stored in a computer-readable recording medium.

### (6) Other Embodiments

The embodiments of the present disclosure have been specifically described above. However, the present disclosure is not limited to the above-described embodiments, and various changes can be made without departing from the gist thereof.

For example, in the above embodiments, the case where the Mo-containing gas is used has been described as an example, but the present disclosure is not limited thereto.

Further, in the above embodiments, the case where the H₂ gas is used as the reducing gas has been described as an example, but the present disclosure is not limited thereto.

Further, in the above embodiments, the example of forming a film using a substrate processing apparatus which is a batch type vertical apparatus for processing a plurality of substrates at one time has been described, but the present disclosure is not limited thereto. The present disclosure is also suitably applicable to a case of forming a film using a single-wafer type substrate processing apparatus for processing one or several substrates at a time.

### (First Modification)

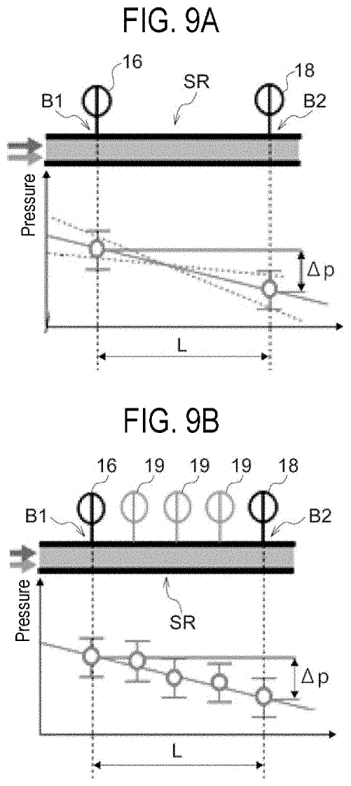

For example, in the present disclosure, one or more third pressure measurers may be further installed between the first position B1 and the second position B2. That is, the number of pressure gauges installed in the pressure measurer may be three or more. FIG. 9A exemplifies a case of two-point measurement using two pressure gauges. In the case of the two-point measurement, an error of the pressure gauge may become large, and as a result, there is a concern that it becomes difficult to accurately estimate Δp/L of the flow rate calculation formula. On the other hand, FIG. 9B exemplifies a measurement method in the case of a first modification in which three pressure gauges as third pressure measurers 19 are installed between the first position B1 and the second position B2.

In the first modification, the pressures at three or more points are measured, and the pressure loss (pressure gradient) between the first position B1 and the second position B2 can be obtained with higher accuracy by a minimum square approximation method using the measured multiple pressures. That is, an error of the pressure gauge can be reduced. Therefore, the calculation accuracy of the flow rate can be improved. In particular, the first modification is useful when a differential pressure is small with respect to the full scale of the pressure gauge and an error of each pressure gauge cannot be ignored with respect to the accuracy required for the flow rate calculation.

When measuring the pressures at three or more points as in the first modification, the controller 121 uses the first pressure measurer 16, the second pressure measurer 18, and the third pressure measurers to calculate the flow rate of the precursor gas.

When the first pressure measurer 16, the second pressure measurer 18, and one or more third pressure measurers are installed, in the process of calculating the flow rate of the precursor gas, it is selected whether to use two pressure measurers or all pressure measurers. Specifically, the controller 121 is installed with both an arithmetic program using two pressure measurers and an arithmetic program using all pressure measurers, and is configured so as to be capable of changing an arithmetic program used for processing according to the number of selected pressure measurers.

When two pressure measurers are used, the controller 121 can select any two pressure measurers from the first pressure measurer 16, the second pressure measurer 18, and the third pressure measurers, and performs the process of calculating the flow rate of the precursor gas using the two selected pressure measurers. When all the pressure measurers are used, the controller 121 performs the process of calculating the flow rate of the precursor gas using all of the first pressure measurer 16, the second pressure measurer 18, and all of the third pressure measurers.

### (Second Modification)

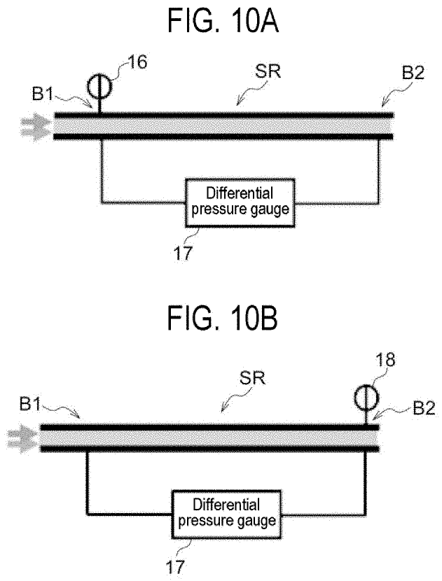

Further, as shown in FIGS. 10A and 10B, in the present disclosure, one of the pressure gauges of the first pressure measurer 16 on the upstream side and the second pressure measurer 18 on the downstream side may be replaced with a differential pressure gauge 17 to measure the pressure of each of the first position B1 and the second position B2. FIG. 10A exemplifies a case where the differential pressure gauge 17 is arranged at the second position B2 in place of the pressure gauge, and FIG. 10B exemplifies a case where the differential pressure gauge 17 is arranged at the first position B1 in place of the pressure gauge.

As the differential pressure gauge 17, specifically, for example, a differential pressure gauge that is a type of measuring using a diaphragm can be used. By using the differential pressure gauge 17, a measurement error due to the zero point deviation of the pressure gauge is less likely to occur as compared with the case of using two pressure gauges, and as a result, the flow rate measurement accuracy can be improved.

### (Third Modification)

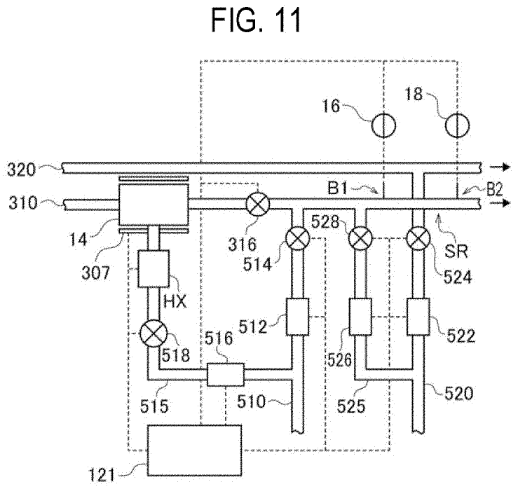

Further, as shown in FIG. 11, in the present disclosure, a temperature controller HX for controlling the temperature of the first inert gas may be installed on the upstream side of the container 14. The temperature controller HX is connected to the controller 121. The temperature controller HX can include, for example, a pipe heater that can control the temperature, a temperature sensor, and the like.

In the third modification, the temperature of the first inert gas can be changed through the temperature controller HX by the feedback control of the controller 121 during film formation. By changing the temperature of the first inert gas, the internal temperature of the container 14 that vaporizes the precursor changes, and the saturated vapor pressure of the precursor changes according to the change of the internal temperature of the container 14. Therefore, it is possible to control the maximum amount of vaporization of the precursor.

For example, when the temperature controller HX is operated so as to increase the temperature of the first inert gas, the internal temperature of the container 14 rises, so that the saturated vapor pressure rises. Therefore, the amount of precursor that can be vaporized in the container 14 increases, and as a result, the flow rate of the precursor to be supplied to the process chamber 201 can be increased. Further, by changing the temperature of the container 14 after the first inert gas is supplied to the container 14, the saturated vapor pressure of the precursor can be changed quickly.

According to the present disclosure in some embodiments, it is possible to provide a technique capable of allowing a gas to stably flowing at a large flow rate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A gas supply system comprising:
a container in which a gas is generated;
a first pipe connected between the container and a reaction chamber, and including a straight pipe portion;
a first pressure measurer installed at a first position of the straight pipe portion, and configured to measure a pressure of the gas;
a second pressure measurer installed at a second position on a further downstream side of a flow of the gas than the first position of the straight pipe portion, and configured to measure a pressure of the gas; and
a controller configured to be capable of calculating a flow rate of the gas flowing through the straight pipe portion based on a pressure loss of the straight pipe portion, which is calculated from a measurement signal from the first pressure measurer and a measurement signal from the second pressure measurer, and controlling the flow rate of the gas based on a calculation result.

2. The gas supply system of claim 1, further comprising:
a second pipe connected to the container, and configured to supply a first inert gas to the container; and
a first inert gas supplier installed in the second pipe, and configured to be capable of measuring a flow rate of the first inert gas flowing through the second pipe,
wherein the controller calculates a flow rate of a precursor in the gas generated in the container based on the calculated flow rate of the gas flowing through the straight pipe portion and the flow rate of the first inert gas.

3. The gas supply system of claim 2, wherein the controller calculates a concentration of the precursor in the gas flowing through the straight pipe portion based on the calculated flow rate of the gas flowing through the straight pipe portion, the flow rate of the first inert gas, a characteristic of the gas, and a characteristic of the first inert gas.

4. The gas supply system of claim 2, further comprising:
a third pipe connected to the first pipe, and configured to supply a second inert gas to the first pipe; and
a second inert gas supplier installed in the third pipe, and configured to be capable of measuring a flow rate of the second inert gas flowing through the third pipe,
wherein the controller calculates the flow rate of the precursor in the gas generated in the container based on the calculated flow rate of the gas flowing through the straight pipe portion, the flow rate of the first inert gas, and the flow rate of the second inert gas.

5. The gas supply system of claim 3, further comprising:
a third pipe connected to the first pipe, and configured to supply a second inert gas to the first pipe; and
a second inert gas supplier installed in the third pipe to be capable of measuring a flow rate of the second inert gas flowing through the third pipe,
wherein the controller calculates the flow rate of the precursor in the gas generated in the container based on the calculated flow rate of the gas flowing through the straight pipe portion, the flow rate of the first inert gas, and the flow rate of the second inert gas.

6. The gas supply system of claim 4, wherein the controller calculates a concentration of the precursor in the gas flowing through the straight pipe portion based on the calculated flow rate of the gas flowing through the straight pipe portion, the flow rate of the first inert gas, the flow rate of the second inert gas, a characteristic of the gas, a characteristic of the first inert gas, and a characteristic of the second inert gas.

7. The gas supply system of claim 1, wherein the controller calculates a flow rate of a precursor in the gas flowing through the straight pipe portion based on a difference between a pressure value as the measurement signal of the first pressure measurer and a pressure value as the measurement signal of the second pressure measurer.

8. The gas supply system of claim 1, further comprising: one or more third pressure measurers installed between the first position and the second position,
wherein the controller calculates a flow rate of a precursor in the gas flowing through the straight pipe portion by using the first pressure measurer, the second pressure measurer, and the one or more third pressure measurers.

9. The gas supply system of claim 8, wherein the controller is configured to be capable of switching between a process of calculating the flow rate of the gas by using two of the first pressure measurer, the second pressure measurer, and the one or more third pressure measurers and a process of calculating the flow rate of the precursor in the gas flowing through the straight pipe portion by using the first pressure measurer, the second pressure measurer, and the one or more third pressure measurers.

10. The gas supply system of claim 2, wherein the controller is configured to be capable of adjusting the flow rate of the first inert gas to be supplied to the container by controlling the first inert gas supplier based on the calculated flow rate of the gas flowing through the straight pipe portion.

11. The gas supply system of claim 10, wherein the controller is configured to be capable of controlling the first inert gas supplier so as to increase the flow rate of the first inert gas when a decrease in the flow rate of the gas flowing through the straight pipe portion is detected by the calculation, and to decrease the flow rate of the first inert gas when an increase in the flow rate of the gas flowing through the straight pipe portion is detected by the calculation.

12. The gas supply system of claim 4, wherein the controller is configured to be capable of adjusting the flow rate of the second inert gas to be supplied to the container by controlling the second inert gas supplier based on the calculated flow rate of the gas flowing through the straight pipe portion.

13. The gas supply system of claim 12, wherein the controller is configured to be capable of controlling the second inert gas supplier so as to decrease the flow rate of the second inert gas when the flow rate of the first inert gas is increased, and to increase the flow rate of the second inert gas when the flow rate of the first inert gas is decreased.

14. The gas supply system of claim 1, wherein both the first pressure measurer and the second pressure measurer are configured by an absolute pressure gauge.

15. A substrate processing apparatus, comprising:
a reaction chamber in which a substrate is processed;
a container in which a gas is generated;
a first pipe connected between the container and the reaction chamber, and including a straight pipe portion;
a first pressure measurer installed at a first position of the straight pipe portion, and configured to measure a pressure of the gas;
a second pressure measurer installed at a second position on a further downstream side of a flow of the gas than the first position of the straight pipe portion, and configured to measure a pressure of the gas; and
a controller configured to be capable of calculating a flow rate of the gas flowing through the straight pipe portion based on a pressure loss of the straight pipe portion, which is calculated from a measurement signal from the first pressure measurer and a measurement signal from the second pressure measurer, and controlling the flow rate of the gas based on a calculation result.

16. A method of processing a substrate by using the gas supply system of claim 1, comprising:
supplying the gas with the flow rate controlled to the substrate in the reaction chamber.

17. A method of manufacturing a semiconductor device, comprising the method of claim 16.

18. A non-transitory computer-readable recording medium storing a program that causes, by a computer, the gas supply system of claim 1 to perform a process comprising:
generating the gas in the container; and
calculating the flow rate of the gas flowing through the straight pipe portion based on the pressure loss of the straight pipe portion, which is calculated from the measurement signal from the first pressure measurer and the measurement signal from the second pressure measurer, and controlling the flow rate of the gas based on a calculation result.
